(19) United States
(12) Patent Application Publication
(10) Pub. No.: US 2025/0346148 A1
(43) Pub. Date: Nov. 13, 2025

(54) V2L CONVERTER FOR VEHICLE AND METHOD OF CONTROLLING THE SAME

(71) Applicant: Hyundai Kefico Corporation, Gunpo (KR)

(72) Inventors: Joo Yong Kim, Incheon (KR); Sang Jae Yoo, Gunpo (KR); Ye Chang Heo, Suwon (KR); Hyun Woo Kim, Suwon (KR); Dong Woo Seo, Anyang (KR); Jun Woo Park, Anyang (KR)

(21) Appl. No.: 19/200,451

(22) Filed: May 6, 2025

(30) Foreign Application Priority Data
May 7, 2024 (KR) 10-2024-0060117

(51) Int. Cl. B60L 55/00; B60L 1/00; H02J 7/00; H02M 7/5387; H02M 7/5395

(52) U.S. Cl. CPC B60L 55/00; B60L 1/006; H02J 7/00304; H02J 7/0047; H02J 7/0063; H02M 7/53871; H02M 7/5395; B60L 2210/10; B60L 2210/42; H02J 2207/20; H02J 2310/14

(57) ABSTRACT

A vehicle to load (V2L) converter for a vehicle includes a high voltage battery unit configured to supply power of an electric vehicle, a DC/DC converter unit configured to convert the supplied power to a voltage so that the voltage is output as a constant voltage, a DC/AC inverter unit including a plurality of field effect transistors (FETs) and configured to perform power transfer and control corresponding to the converted constant voltage through a switching operation, and a burst circuit unit configured to change a switching operation per unit time of the DC/AC inverter unit upon overload operation.

### CROSS-REFERENCE TO RELATED APPLICATION

This application claims priority to and the benefit of Korean Patent Application No. 10-2024-0060117 filed on May 7, 2024, the disclosures of which are incorporated herein by reference in their entirety

### BACKGROUND

### 1. Technical Field

The present disclosure relates to a vehicle to load (V2L) converter for a vehicle and a method of controlling the same.

### 2. Related Art

FIG. 1 is a diagram for describing a vehicle to load (V2L) converter 10 according to a conventional technology.

In general, the existing V2L converter 10 is a device that converts power of an internal high voltage battery into 220 V or 110 V, that is, commercial power, so that general household electrical appliances can be used in vehicles, such as an electric vehicle or a hybrid electric vehicle (HEV). In general, the device has a maximum of an output capacity of 3.6 kW, that is, a household rated capacity. To this end, elements, such as a field effect transistor (FET) that is used to basically transfer power, may be used.

However, a special load may perform an overload operation that exceeds an operation using a rated capacity. In such a case, a FET having higher specifications needs to be applied. In order to control such an overload operation, an additional circuit may be required. Furthermore, the overload operation may cause damage to a switching element. There is a need for a complementary circuit for such damage.

### PRIOR ART DOCUMENT

### Patent Document

Korean Patent Application Publication No. 10-2023-0033427 (Mar. 8, 2023)

### SUMMARY

Various embodiments are directed to providing a V2L converter for a vehicle, which can handle an overload operation by introducing a burst circuit that limits the output of a vehicle to load (V2L) converter when an overcurrent is generated, and a method of controlling the same.

However, objects of the present disclosure to be achieved are not limited to the aforementioned object, and other objects may be present.

A V2L converter for a vehicle according to a first aspect of the present disclosure includes a high voltage battery unit configured to supply power of an electric vehicle, a DC/DC converter unit configured to convert the supplied power to a voltage so that the voltage is output as a constant voltage, a DC/AC inverter unit including a plurality of field effect transistors (FETs) and configured to perform power transfer and control corresponding to the converted constant voltage through a switching operation, and a burst circuit unit configured to change a switching operation per unit time of the DC/AC inverter unit upon overload operation.

In some embodiments of the present disclosure, the burst circuit unit may include a comparator configured to determine whether the value of an output current of the DC/AC inverter unit is greater than a preset threshold through a current sensor, a logic gate configured to output a control signal for controlling a gate driver based on the results of the determination, and the gate driver configured to operate to block or output a pulse width modulation (PWM) signal based on the control signal.

In some embodiments of the present disclosure, the comparator may determine whether the value of the output current is greater than the preset threshold set as a positive peak value or a negative peak value.

In some embodiments of the present disclosure, the logic gate may output a gate driver deactivation signal as the control signal when the value of the output current is greater than the preset threshold, and may output a gate driver activation signal as the control signal when the value of the output current is equal to or smaller than the preset threshold.

In some embodiments of the present disclosure, when the comparator determines that the value of the output current is greater than the preset threshold, the gate driver may stop the switching operation of the DC/AC inverter unit by blocking the PWM signal based on the control signal.

In some embodiments of the present disclosure, when the switching operation is stopped, the comparator may determine whether the value of the output current of the DC/AC inverter unit becomes equal to or smaller than the preset threshold through the current sensor. When the comparator determines that the value of the output current becomes equal to or smaller than the preset threshold, the gate driver may activate a switching operation of the DC/AC inverter unit by outputting the PWM signal based on the control signal.

Furthermore, a control method performed by the V2L converter according to a second aspect of the present disclosure includes converting, by a DC/DC converter unit, power supplied from a high voltage battery unit of an electric vehicle into a voltage so that the voltage is output as a constant voltage, performing, by a DC/AC inverter unit including a plurality of field effect transistors (FETs), power transfer and control corresponding to the converted constant voltage through a switching operation, and changing, by a burst circuit unit, a switching operation per unit time of the DC/AC inverter unit upon overload operation.

A computer program according to another aspect of the present disclosure executes the V2L converter for a vehicle and the method of controlling the same in combination with a computer, that is, hardware, and is stored in a computer-readable medium.

Other details of the present disclosure are included in the detailed description and the drawings.

According to the embodiment of the present disclosure, it is not necessary to apply a specific element, such as a FET having excessive specifications because a situation in which an excessive current flows is prevented by an excessive output limiting function of the V2L converter. Accordingly, design and manufacturing costs for a device can be reduced, and productivity can be improved.

Furthermore, damage to an element upon overload operation can be prevented. That is, an overload that is applied to an element can be reduced and damage to an element can be prevented by limiting an output current through the burst circuit unit. Accordingly, reliability of a V2L converter can be improved, and safe power supply to a user can be guaranteed.

Effects of the present disclosure which may be obtained in the present disclosure are not limited to the aforementioned effects, and other effects not described above may be evidently understood by a person having ordinary knowledge in the art to which the present disclosure pertains from the following description.

### BRIEF DESCRIPTION OF THE DRAWINGS

The accompanying drawings are provided to help understanding of the present embodiments and provide the embodiments along with the detailed description. However, the technical characteristics of the present embodiments are not limited to a specific drawing, and characteristics disclosed in the drawings may be combined to form a new embodiment.

FIG. 1 is a diagram for describing a V2L converter according to a conventional technology.

FIG. 2 is a diagram schematically illustrating a common V2L converter.

FIG. 3 is a diagram illustrating signal waveforms in the V2L converter.

FIG. 4 is a diagram illustrating a construction of a V2L converter for a vehicle according to an embodiment of the present disclosure.

FIG. 5 is a diagram for describing a burst circuit unit according to an embodiment of the present disclosure.

FIG. 6 is a flowchart regarding a method of controlling a V2L converter according to an embodiment of the present disclosure.

FIG. 7 is a diagram for describing an operation of a burst circuit unit according to an embodiment of the present disclosure.

FIGS. 8A to 8C are diagrams for describing effects of the present disclosure.

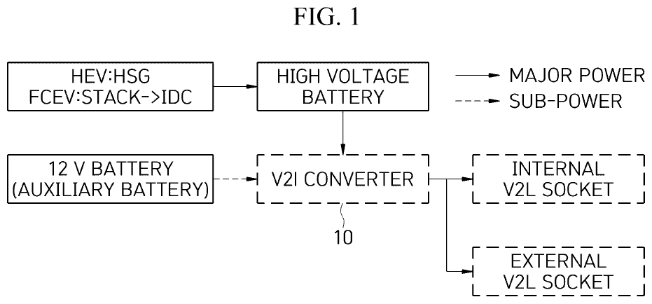

### DETAILED DESCRIPTION

Advantages and characteristics of the present disclosure and a method for achieving the advantages and characteristics will become apparent from the embodiments described in detail later in conjunction with the accompanying drawings. However, the present disclosure is not limited to embodiments disclosed hereinafter, but may be implemented in various different forms. The embodiments are merely provided to complete the present disclosure and to fully notify a person having ordinary knowledge in the art to which the present disclosure pertains of the category of the present disclosure. The present disclosure is merely defined by the claims.

Terms used in this specification are used to describe embodiments and are not intended to limit the present disclosure. In this specification, an expression of the singular number includes an expression of the plural number unless clearly defined otherwise in the context. The term “comprises” and/or “comprising” used in this specification does not exclude the presence or addition of one or more other elements in addition to a mentioned element. Throughout the specification, the same reference numerals denote the same elements. “And/or” includes each of mentioned elements and all combinations of one or more of mentioned elements. Although the terms “first”, “second”, etc. are used to describe various components, these elements are not limited by these terms. These terms are merely used to distinguish between one element and another element. Accordingly, a first element mentioned hereinafter may be a second element within the technical spirit of the present disclosure.

All terms (including technical and scientific terms) used in this specification, unless defined otherwise, will be used as meanings which may be understood in common by a person having ordinary knowledge in the art to which the present disclosure pertains. Furthermore, terms defined in commonly used dictionaries are not construed as being ideal or excessively formal unless specially defined otherwise.

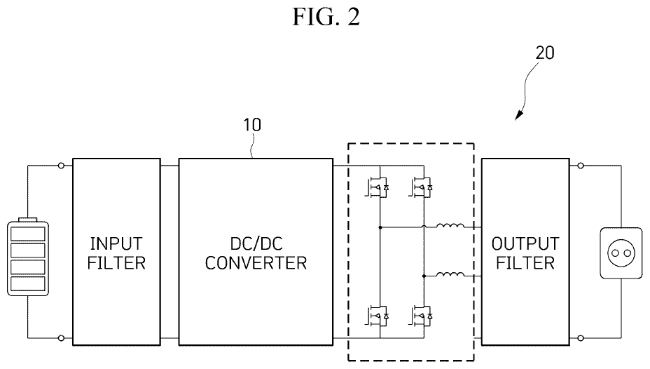

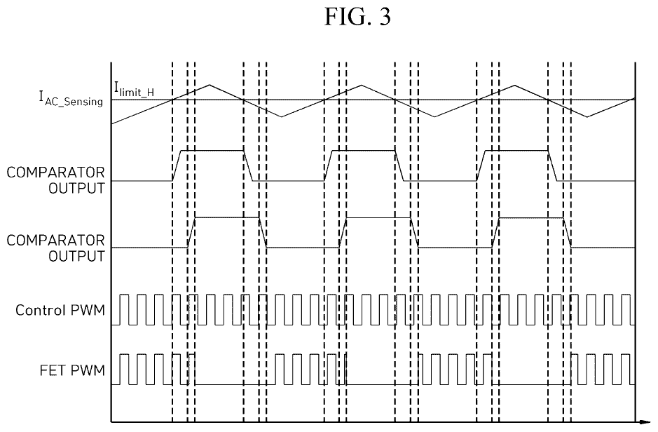

FIG. 2 is a diagram schematically illustrating a common V2L converter (V2LC) 20. FIG. 3 is a diagram illustrating signal waveforms in the V2LC.

The V2LC 20 is a device that generates household power (e.g., 220 V AC or 110 V AC) from an internal high voltage battery of an electric-driven type (HEV, FCEV, or EV) vehicle and supplies the generated household power to the outside of the electric-driven type vehicle. Accordingly, a user can conveniently use common household appliances (e.g., a laptop, a microwave, and TV) within the electric-driven type vehicle.

In this case, an overpower load which may occur is a special load greater than a household power capacity (e.g., about 3.6 kW) that is commonly supported by the V2LC 20. For example, a high power consumption device, such as an electric saw, a compressor, or a laptop charger, may have a characteristic in that the capacity of the high power consumption device is several times its rated capacity in a transient state.

When a special control method is not applied in order to operate the overpower load in the V2LC 20, a power element having excessive specifications is required, resulting in a problem with a rise in unit cost. In order to prevent the problem, a burst circuit that adjusts the number of times of switching per unit time in a specific condition is introduced into the V2L converter for a vehicle.

Accordingly, it is possible to limits an output in the overcurrent situation. In particular, a power element having excessive specifications is not required and damage to an element attributable to the overcurrent can be prevented by applying an analog burst circuit capable of handling an overcurrent rise speed upon overload operation.

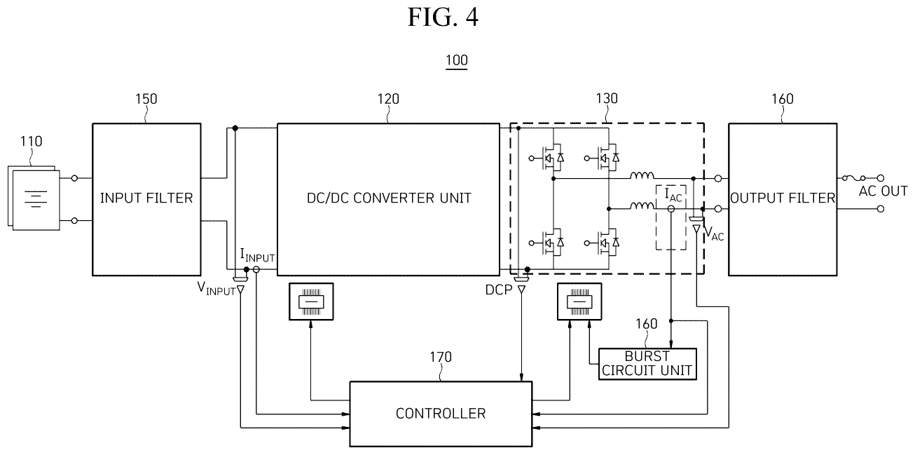

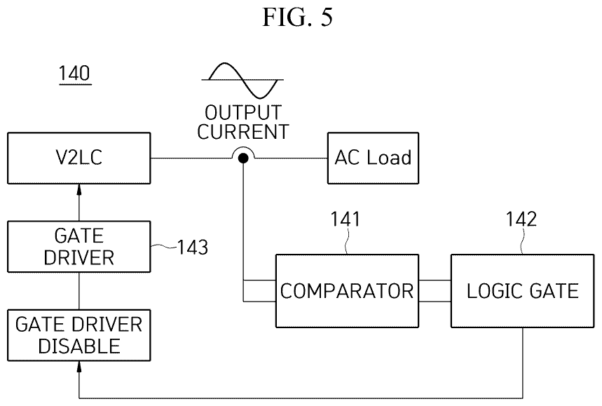

FIG. 4 is a diagram illustrating a construction of a V2L converter 100 for a vehicle according to an embodiment of the present disclosure. FIG. 5 is a diagram for describing the burst circuit unit 140 according to an embodiment of the present disclosure.

The V2L converter 100 for a vehicle according to an embodiment of the present disclosure includes a high voltage battery unit 110, a DC/DC converter unit 120, a DC/AC inverter unit 130, and a burst circuit unit 140. In addition, the V2L converter 100 for a vehicle may further include an input filter 150, an output filter 160, and a controller 170 that controls all of the components.

The high voltage battery unit 110 supplies power of an electric vehicle. The high voltage battery unit 110 is charged with a high voltage. The charged power is converted into common household power through the V2L converter 100 so that the common household power can be used in various electronic devices.

The DC/DC converter unit 120 converts a voltage received from the high voltage battery unit 110 into a constant voltage so that the constant voltage is stably maintained and can be converted into efficient power.

The DC/AC inverter unit 130 includes a plurality of FET elements and performs power transfer and control corresponding to a converted constant voltage through a switching operation.

The burst circuit unit 140 changes a switching operation per unit time of the DC/AC inverter unit 130 upon overload operation. That is, the burst circuit unit 140 limits an overload operation by adjusting the switching operation per unit time of the DC/AC inverter unit 130 upon overload operation in order to protect an element.

Specifically, the burst circuit unit 140 may include a comparator 141, a logic gate 142, and a gate driver 143.

The comparator 141 determines whether the value of an output current of the DC/AC inverter unit 130 is greater than a preset threshold through a current sensor. The current sensor may sense the value of the output current of the DC/AC inverter unit 130. The comparator 141 may determine whether the state of the burst circuit unit 140 is an overcurrent state by comparing the sensed output current value with the preset threshold. Furthermore, the comparator 141 transmits a comparison result between the value of the output current and the preset threshold to the logic gate 142.

The comparator 141 may determine whether the value of the output current of the DC/AC inverter unit 130 is greater than the preset threshold set as a positive peak value or a negative peak value. That is, in an embodiment of the present disclosure, the positive and negative peaks of a current may be considered in order to accurately sense the overcurrent state.

The logic gate 142 outputs a control signal that controls the gate driver 143 by receiving the comparison result from the comparator 141. According to an embodiment, the logic gate 142 may receive the comparison result when the value of the output current is greater than the preset threshold.

The logic gate 142 may output a gate driver deactivation signal as the control signal when the value of the output current is greater than the preset threshold. In contrast, when the value of the output current is equal to or smaller than the preset threshold, the logic gate 142 may output a gate driver activation signal as the control signal.

The gate driver 143 operates to block or output a pulse width modulation (PWM) signal based on the control signal. That is, the gate driver 143 can solve the overcurrent state and adjust a power flow by controlling an operation of the DC/AC inverter unit 130 through PWM.

In this case, when determining that the value of the output current is greater than the preset threshold, the gate driver 143 may stop a switching operation of the DC/AC inverter unit 130 by blocking the PWM signal based on the control signal. When the switching operation of the DC/AC inverter unit 130 is stopped, the output of the DC/AC inverter unit 130 is blocked.

Thereafter, the comparator 141 determines whether the value of the output current of the DC/AC inverter unit 130 becomes equal to or smaller than the preset threshold through the current sensor as the switching operation is stopped. Furthermore, when the value of the output current of the DC/AC inverter unit 130 becomes equal to or smaller than the preset threshold based on the results of the determination, the logic gate 142 outputs the gate driver activation signal as the control signal. In response thereto, the gate driver 143 may activate a switching operation of the DC/AC inverter unit 130 by outputting the PWM signal again based on the control signal.

In an embodiment of the present disclosure, it is possible to block an excessive output by repeatedly performing an operation of blocking and outputting the PWM signal in the transient state of an overpower load. Accordingly, the V2L converter 100 for a vehicle can operate even without damage to a power element.

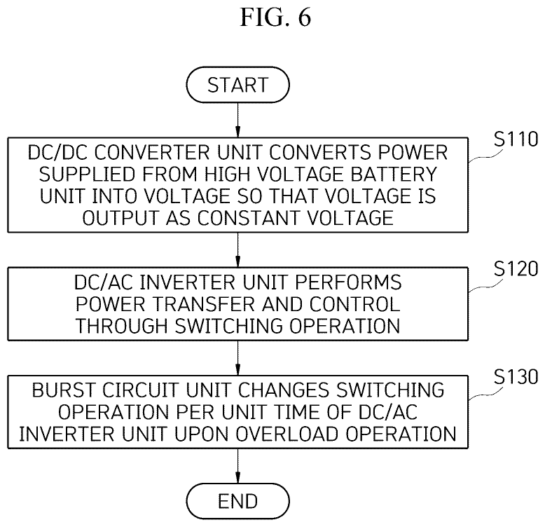

FIG. 6 is a flowchart regarding a method of controlling the V2L converter 100 according to an embodiment of the present disclosure.

First, the DC/DC converter unit 120 converts power supplied from the high voltage battery unit 110 of an electric vehicle into a voltage so that the voltage is output as a constant voltage (S110).

Next, the DC/AC inverter unit 130 including a plurality of FETs performs power transfer and control corresponding to the converted constant voltage through a switching operation (S120).

Next, the burst circuit unit 140 changes the switching operation per unit time of the DC/AC inverter unit 130 upon overload operation (S130).

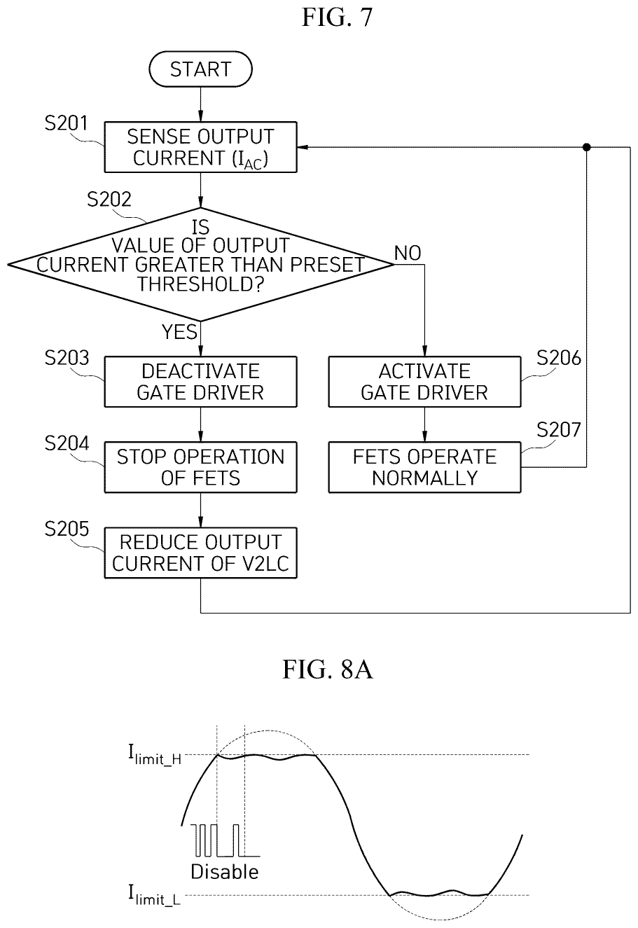

FIG. 7 is a diagram for describing an operation of the burst circuit unit 140 according to an embodiment of the present disclosure.

First, when an overpower load is applied to the V2L converter 100 for a vehicle, an output current rises due to an operation in the transient state.

In this state, when measuring or sensing the value of the output current (S201), the burst circuit unit 140 checks whether a positive peak value or negative peak value of an AC waveform is greater than a preset threshold due to a rise in the value of the output current (S202). In this case, the burst circuit unit 140 checks whether each of both the positive and negative values of the output current is greater than the preset threshold.

Thereafter, when each of both the positive and negative values of the output current is greater than the preset threshold, the logic gate 142 outputs the gate driver deactivation signal. In response thereto, the gate driver 143 is deactivated (S203). An operation of the plurality of FETs of the DC/AC inverter unit 130 is stopped (S204).

Thereafter, the value of the output current is reduced (S205). The burst circuit unit 140 senses the value of the output current again (S201). Thereafter, steps S202 and S203 are repeatedly performed.

Thereafter, when the value of the output current is reduced and each of the positive peak and negative peak of an AC waveform is smaller than a preset threshold, the logic gate 142 outputs the gate driver activation signal. Accordingly, the gate driver 143 is activated (S206). The plurality of FETs of the DC/AC inverter unit 130 operates normally again (S207). Thereafter, the process returns to the step of sensing the value of an output current. The above steps are repeatedly performed in order to limit the output of the burst circuit unit 140 while an overpower load is applied thereto, and the plurality of FETs is controlled to operate within the range of a normal operation.

In the aforementioned description, each of S110 to S207 may be further divided into additional steps or the steps may be combined into smaller r steps depending on an implementation example of the present disclosure. Furthermore, some of the steps may be omitted, if necessary, and the sequence of the steps may be changed. Furthermore, although contents are omitted, the contents of FIGS. 2 to 6 and the contents of FIGS. 6 and 7 may be mutually applied.

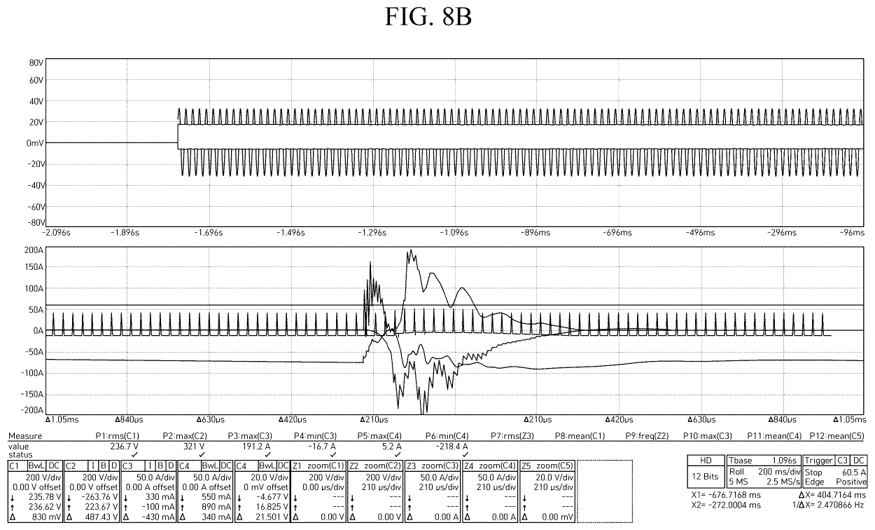

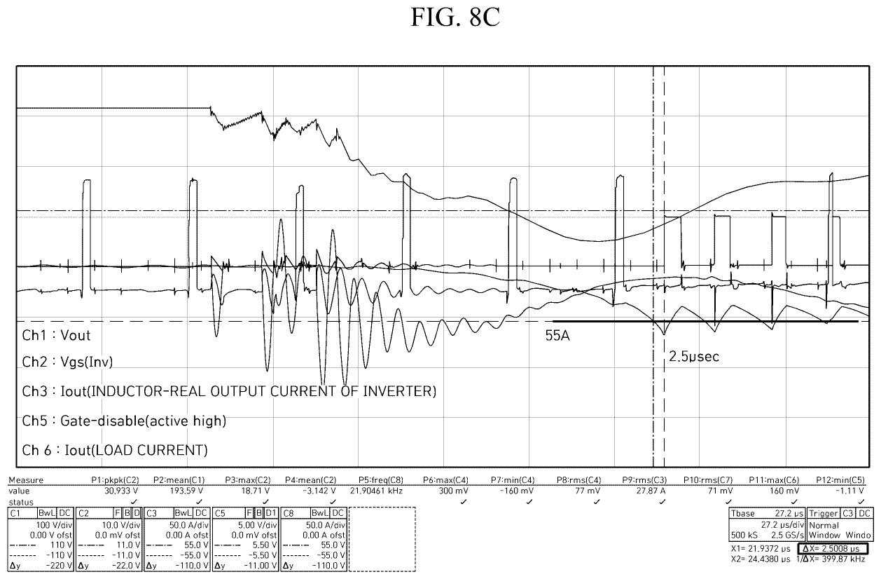

FIGS. 8A to 8C are diagrams for describing effects of the present disclosure.

FIG. 8A illustrates the waveform of a gate signal that is applied to the plurality of FETs when the burst circuit unit 140 operates. When an overcurrent is sensed by the current sensor, the gate signal (i.e., the gate driver deactivation signal) is blocked. Accordingly, the burst circuit unit 140 is controlled to reduce its output current.

FIG. 8B illustrates waveforms upon overload operation. When an overpower load operates, the output current of the burst circuit unit 140 instantly rises up to 218.4 A. If a specific element is applied in order to support a corresponding overcurrent, there is a problem in that the specifications of a rated current are excessively increased by about twice.

FIG. 8C illustrates waveforms in an overload operation when the burst circuit unit 140 is applied. It was checked that the output current of the burst circuit unit 140 is controlled about 10% of a preset threshold when an excessive output is limited through the burst circuit unit 140. Furthermore, it was checked that although an element having rated specifications is used, a load operates normally. Furthermore, it is possible to prevent damage to an element by preventing an element from processing an excessive current even in the excessive power state through the load limiting function.

The method of controlling the V2L converter 100 according to an embodiment of the present disclosure may be implemented in the form of a program (or application) in order to be executed by being combined with a computer, that is, hardware, and may be stored in a medium.

The aforementioned program may include a code coded in a computer language, such as C, C++, JAVA, Python, Ruby, or a machine language which is readable by a processor (CPU) of a computer through a device interface of the computer in order for the computer to read the program and execute the methods implemented as the program. Such a code may include a functional code related to a function, etc. that defines functions necessary to execute the methods, and may include an execution procedure-related control code necessary for the processor of the computer to execute the functions according to a given procedure. Furthermore, such a code may further include a memory reference-related code indicating at which location (address number) of the memory inside or outside the computer additional information or media necessary for the processor of the computer to execute the functions needs to be referred. Furthermore, if the processor of the computer requires communication with any other remote computer or server in order to execute the functions, the code may further include a communication-related code indicating how the processor communicates with the any other remote computer or server by using a communication module of the computer and which information or media needs to be transmitted and received upon communication.

The stored medium means a medium, which semi-permanently stores data and is readable by a device, not a medium storing data for a short moment like a register, cache, or a memory. Specifically, examples of the stored medium include ROM, RAM, CD-ROM, a magnetic tape, a floppy disk, optical data storage, etc., but the present disclosure is not limited thereto. That is, the program may be stored in various recording media in various servers which may be accessed by a computer or various recording media in a computer of a user. Furthermore, the medium may be distributed to computer systems connected over a network, and a code readable by a computer in a distributed way may be stored in the medium.

The description of the present disclosure is illustrative, and a person having ordinary knowledge in the art to which the present disclosure pertains will understand that the present disclosure may be easily modified in other detailed forms without changing the technical spirit or essential characteristic of the present disclosure. Accordingly, it should be construed that the aforementioned embodiments are only illustrative in all aspects, and are not limitative. For example, elements described in the singular form may be carried out in a distributed form. Likewise, elements described in a distributed form may also be carried out in a combined form.

The scope of the present disclosure is defined by the appended claims rather than by the detailed description, and all changes or modifications derived from the meanings and scope of the claims and equivalents thereto should be interpreted as being included in the scope of the present disclosure.

### DESCRIPTION OF REFERENCE NUMERALS

100: V2L converter for vehicle
110: high voltage battery unit
120: DC/DC converter unit
130: DC/AC inverter unit 140: burst circuit unit
141: comparator 142: logic gate
143: gate driver

What is claimed is:

1. A vehicle to load (V2L) converter for a vehicle, comprising:
a high voltage battery unit configured to supply power of an electric vehicle;
a DC/DC converter unit configured to convert the supplied power to a voltage so that the voltage is output as a constant voltage;
a DC/AC inverter unit comprising a plurality of field effect transistors (FETs) and configured to perform power transfer and control corresponding to the converted constant voltage through a switching operation; and
a burst circuit unit configured to change a switching operation per unit time of the DC/AC inverter unit upon overload operation.

2. The V2L converter of claim 1, wherein the burst circuit unit comprises:
a comparator configured to determine whether a value of an output current of the DC/AC inverter unit is greater than a preset threshold through a current sensor;
a logic gate configured to output a control signal for controlling a gate driver based on the results of the determination; and
the gate driver configured to operate to block or output a pulse width modulation (PWM) signal based on the control signal.

3. The V2L converter of claim 2, wherein the comparator determines whether the value of the output current is greater than the preset threshold set as a positive peak value or a negative peak value.

4. The V2L converter of claim 2, wherein the logic gate
outputs a gate driver deactivation signal as the control signal when the value of the output current is greater than the preset threshold, and
outputs a gate driver activation signal as the control signal when the value of the output current is equal to or smaller than the preset threshold.

5. The V2L converter of claim 2, wherein when the comparator determines that the value of the output current is greater than the preset threshold, the gate driver stops the switching operation of the DC/AC inverter unit by blocking the PWM signal based on the control signal.

6. The V2L converter of claim 4, wherein:
when the switching operation is stopped, the comparator determines whether the value of the output current of the DC/AC inverter unit becomes equal to or smaller than the preset threshold through the current sensor, and
when the comparator determines that the value of the output current becomes equal to or smaller than the preset threshold, the gate driver activates a switching operation of the DC/AC inverter unit by outputting the PWM signal based on the control signal.

7. A control method performed by a vehicle to load (V2L) converter, comprising:
converting, by a DC/DC converter unit, power supplied from a high voltage battery unit of an electric vehicle into a voltage so that the voltage is output as a constant voltage;
performing, by a DC/AC inverter unit comprising a plurality of field effect transistors (FETs), power transfer and control corresponding to the converted constant voltage through a switching operation; and
changing, by a burst circuit unit, a switching operation per unit time of the DC/AC inverter unit upon overload operation.
